(19) United States
(12) Patent Application Publication
(10) Pub. No.: US 2012/0076190 A1
(43) Pub. Date: Mar. 29, 2012

(54) METHOD AND APPARATUS FOR DIGITALLY PROCESSING OFDM SIGNALS FOR RADAR APPLICATIONS

(76) Inventors: Christian Sturm, Karlsruhe (DE); Werner Wiesbeck, Keltern (DE); Thomas Zwick, Graben-Neudorf (DE)

(21) Appl. No.: 13/266,306

(22) PCT Filed: Apr. 22, 2010
(86) PCT No.: PCT/DE10/00463

§ 371 Date: Dec. 12, 2011

(30) Foreign Application Priority Data
Apr. 27, 2009 (DE) 10-2009-018.764.2
May 4, 2009 (DE) 10-2009-019.905.5

(51) Int. Cl. H04L 27/28; H03K 9/04

(52) U.S. Cl. 375/224; 375/260

(57) ABSTRACT

The present invention relates to a method and also a device for digitally processing OFDM signals which are emitted by a transmission apparatus with modulation symbols as information carriers, reflected at one or a plurality of objects at least to some extent and received by a receiving apparatus. The modulation symbols are extracted without prior channel equalisation from the OFDM signals received and the extracted modulation symbols are normalised by a complex division to the respectively transmitted modulation symbol. The radar analysis for determining the distance and/or determining the speed of the objects then takes place on the basis of the normalised modulation symbols. With the method and the device, on the one hand, both distance and speed of the objects can be determined independently of one another. On the other hand, the method works very reliably, as it is not influenced by the transmitted information.

### TECHNICAL FIELD OF APPLICATION

The present invention relates to a method and a device for digitally processing OFDM signals which are transmitted by a transmission apparatus with modulation symbols as information carriers, reflected at one or a plurality of objects at least to some extent and received by a receiving apparatus, the modulation symbols being extracted from the received OFDM signals.

For radio sensors, in addition to military applications, there are also numerous civil applications, for example in the field of intelligent driver assistance systems (Tempomat radar, collision prevention) or in the monitoring of production processes. Radar technology offers the advantage compared to other sensor technologies, that using it, both distances and speeds can be determined rapidly and precisely and radar sensors are resistant to external influences, such as vapours, rain or fog.

### PRIOR ART

Different classical methods and hardware designs exist in the field of radar technology, in which signal processing takes place to a large extent analogously in electronic circuits. Examples for this are chirp radar, pulse radar or FMCW radar (FMCW: Frequency Modulated Continuous Wave). These methods are to a large extent exhausted and optimised. Thanks to the capability which has become available in the meantime in the field of digital processing, completely new possibilities have opened up both with regards to the shaping of novel transmission signals and with regards to the application of complex processing algorithms in the receiver. The capability of future radar sensors will therefore mainly be determined by the signal shapes and digital processing methods used.

The present invention is concerned with the digital processing and use of OFDM signals (OFDM: Orthogonal Frequency Division Multiplex) for an application in radar sensor technology. The generation of OFDM technology can here take place in the digital plane. Hitherto, OFDM technology was primarily used for information or data transmission, as the OFDM signal is composed of modulation symbols and is therefore used in a targeted manner for information transmission. The use of OFDM technology for radar applications has also been discussed already. So, for example, A. Garmatyuk et al. show an OFDM radar system which can be used for information transmission at the same time in “Feasibility study of a multi-carrier dual-use imaging radar and communication system”, in Proc. 37th European Microwave Conference, pages 1473 to 1476, October 2007. In this implementation of OFDM radar, a cross correlation of the received signal with the transmitted signal is carried out for the processing of the OFDM radar signals in the receiver. If x(t) designates the transmitted baseband signal and y(t) designates the received baseband signal, then this process can be described mathematically with the following equation:

φ_{yx}(τ)=∫y(t)x(t−τ)dt (1)

However, the dynamic achievable by means of this processing is dependent on the autocorrelation properties of the transmission signal. In order to be able to achieve a high dynamic, special codes must be transmitted, such as M sequences for example. The properties of the same then determine the dynamic. Should the system be used for simultaneous information transmission however, then the achievable dynamic cannot be predicted, as it depends on the autocorrelation properties of the information transmitted. Reliable operation is therefore not possible. Furthermore, although the distance of objects can be determined with processing on the basis of cross correlation, the speed thereof cannot.

The object of the present invention consists in specifying a method and also a device for processing OFDM signals, which, in the case of simultaneous use of these signals for radar and for information transmission, enables reliable operation and also, if required, the determining of the speed of objects.

### DESCRIPTION OF THE INVENTION

The object is achieved with the method and the device according to the Patent Claims 1 and 8.

Advantageous configurations of the method as well as of the device are the subject matter of the dependent patent claims or can be drawn from the following description as well as from the exemplary embodiment.

In the case of the suggested method for digitally processing OFDM signals, the modulation symbols transmitted, which can also be designated as data symbols, are initially extracted without prior channel equalisation from the OFDM signals received. These extracted modulation symbols or at least some of these modulation symbols are then normalised by a complex division to the respectively originally transmitted modulation symbol. The radar analysis for determining the distance and/or determining the speed of the objects at which the OFDM signals were reflected, then takes place on the basis of the normalised modulation symbols. The radar analysis for determining the distance and/or determining the speed of the objects in this case in particular comprises the creation of a radar image, from which the distance of the objects or the distance and speed of the objects can be derived.

With the suggested method and the device for carrying out the method mentioned further below, the radar processing becomes completely independent of the transmitted information or the transmitted data. This is achieved by the normalisation of the modulation symbols extracted from the signal to the originally transmitted modulation symbols. No special codes are needed, so the OFDM radar signal with any desired user data, which should be transmitted via the common OFDM signal, can be modulated. Due to the independence of the transmitted information, a very high dynamic can be achieved, which is only limited by the side lobes of the required Fourier transformation and noise. A particular advantage of the suggested method and the associated device consists in it being possible to determine the distance of the objects independently of the speed thereof. Distance and speed are not linked to one another here. During the determining of the speed, the integration duration and thus the Doppler resolution or speed resolution can be adapted as desired during operation. The computing outlay necessary for the method is comparatively low, as no cross correlation must be calculated, as was previously the case in the prior art.

In the suggested method, the processing of the radar signals is not carried out with the aid of the baseband signals, rather with the aid of the transmitted and received modulation symbols. To this end, these are tapped in the receiver before the optional equalisation, as at these points they still contain the complete distortions occurring at transmission, which ultimately contain the information about reflected objects. Each received and selected modulation symbol is normalised in terms of amplitude and phase with the aid of a complex division by the transmitted modulation symbol. This normalisation makes the method completely independent of the transmitted modulation symbols. The calculation of the radar image for determining the distance takes place subsequently by means of an inverse Fourier transformation.

The analysis of the Doppler information for determining the relative speed of reflecting objects preferably takes place with the aid of a Fourier transformation by means of temporally consecutive OFDM symbols. The duration of the OFDM symbols is parameterised suitably for this. This processing is likewise based on the modulation symbols and not on the baseband signals.

In the present method, for the discrete Fourier transformations or inverse Fourier transformations carried out for determining the distance and/or speed, in each case all transmitted modulation symbols of an OFDM symbol or a sequence of OFDM signals or else only several of these modulation symbols can be used. In the analysis itself, preferably both distance and speed of the objects, at which the OFDM signals were reflected, are determined. Of course, the method and the associated device can however also be operated in such a manner that only the distance or only the speed is determined from the received OFDM signals.

In the known manner, the suggested device for carrying out the method comprises a receiving antenna, using which OFDM signals can be received, a mixing apparatus for downmixing the received signals, an analogue/digital converter for the digitisation of the signals and also a processing apparatus which extracts the modulation symbols from these signals, normalises the same to the transmitted modulation symbols and on the basis of these normalised modulation symbols carries out a radar analysis for determining the distance and/or speed of the objects at which the signals were reflected. The device can in this case be configured in the manner of a conventional receiver for OFDM signals, whereby only the processing unit is designed for carrying out the suggested method, i.e. extracts the modulation symbols without prior channel equalisation and on the basis of these modulation symbols, carries out the radar analysis for distance determination and/or speed determination, in particular computes the corresponding radar or Doppler images.

### SHORT DESCRIPTION OF THE DRAWINGS

The suggested method and the associated device are explained in detail once more below with reference to an exemplary embodiment in connection with the drawings. In the figures:

FIG. 1 shows a schematic illustration of the structure of an OFDM transmission signal;

FIG. 2 shows a comparison of a radar image from classical processing with a radar image which has been obtained in accordance with the suggested method;

FIG. 3 shows a schematic illustration for determining the speed;

FIG. 4 shows a schematic illustration for determining the distance;

FIG. 5 shows an example of a processed radar image;

FIG. 6 shows a schematic illustration of an OFDM transmitter; and

FIG. 7 shows a schematic illustration of an OFDM receiver.

### WAYS OF CARRYING OUT THE INVENTION

The entire processing when carrying out the suggested method is described in detail in the following on the basis of an exemplary embodiment. In this case, example results, which were calculated with the aid of a computer simulation, are also shown.

An OFDM signal is described in the time domain as follows:

$$x ( t ) = {\sum }_{μ = 0}^{∞} {\sum }_{n = 0}^{N - 1} I ( μ N + n ) {ψ}_{n} ( t - μ T ) \qquad ( 2 )$$

I describes the modulation symbols to be transmitted, which were already generated by means of discrete phase modulation (e.g. PSK; phase shift keying) from the binary information to be transmitted. The index n indexes the, in total, N OFDM subcarriers, μ indexes the temporally consecutive OFDM symbols and Ψₙ represents the orthogonal OFDM subcarriers with:

$${ψ}_{n} ( t ) = exp ( j2π {f}_{n} t ) \frac{1}{\sqrt{T}} rect ( \frac{t}{T} ) , n = 0 , … , N - 1 \qquad ( 3 )$$

wherein Δf=1/T must be true for the distance of the subcarriers to ensure orthogonality. In this case, T is the OFDM symbol duration.

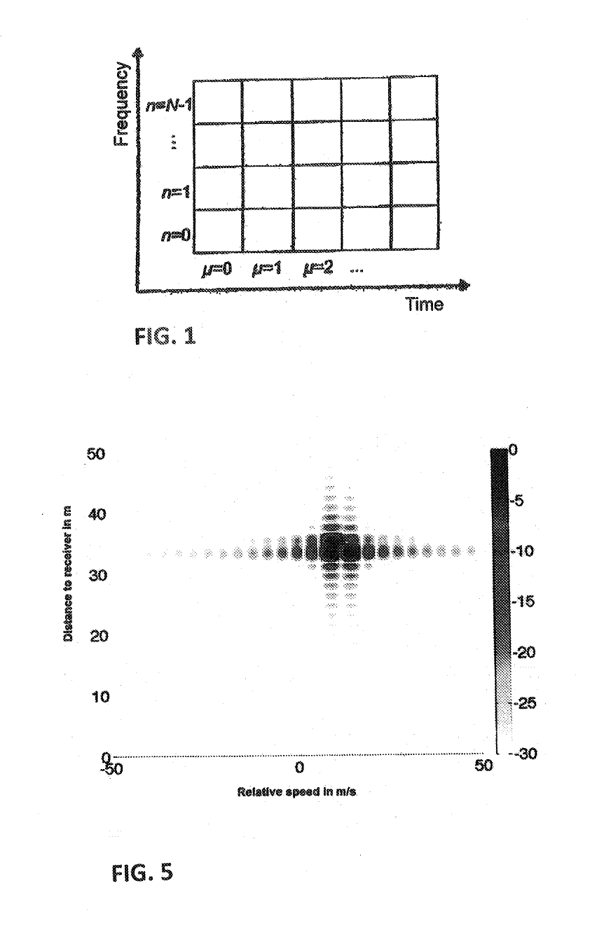

The construction of the OFDM transmission signal from individual modulation symbols can also be shown with the aid of a matrix, as is shown in FIG. 1. Each cell of the matrix contains a modulation symbol, each column of the matrix constitutes an OFDM symbol in each case.

For simpler discussion of the procedure for normalising the modulation symbols and determining the distance or a radar image on the basis of the modulation symbols, the first OFDM symbol is now considered exclusively with μ=0. The time signal of this OFDM symbol can be expressed as:

$$x ( t ) = {\sum }_{n = o}^{N - 1} I ( n ) exp ( j2π {f}_{n} t ) , 0 \leq t \leq T \qquad ( 4 )$$

In the receiver, the OFDM signal is decoded, the individual received modulation symbols Iᵣ are used for processing directly after the discrete Fourier transformation in the OFDM receiver and still before the channel equalisation. Normalisation takes place by means of a complex division:

$${I}_{div} ( n ) = \frac{{I}_{r} ( n )}{I ( n )} \qquad ( 5 )$$

The radar image in the range direction is obtained by means of an inverse discrete Fourier transformation of the normalised modulation symbols.

$$h ( k ) = IDFT ( \{ {I}_{div} ( n ) \} ) = \frac{1}{N} {\sum }_{n = 0}^{N - 1} {I}_{div} ( n ) exp ( j \frac{2 π}{N} nk ) , \\ k = 0 , … , N - 1 \qquad ( 6 )$$

In this case, k is the discrete time variable. The clarity is limited to the distance dₘₐₓ=Tc₀/2 and the dynamic is only limited by the side lobes of the Fourier transformation.

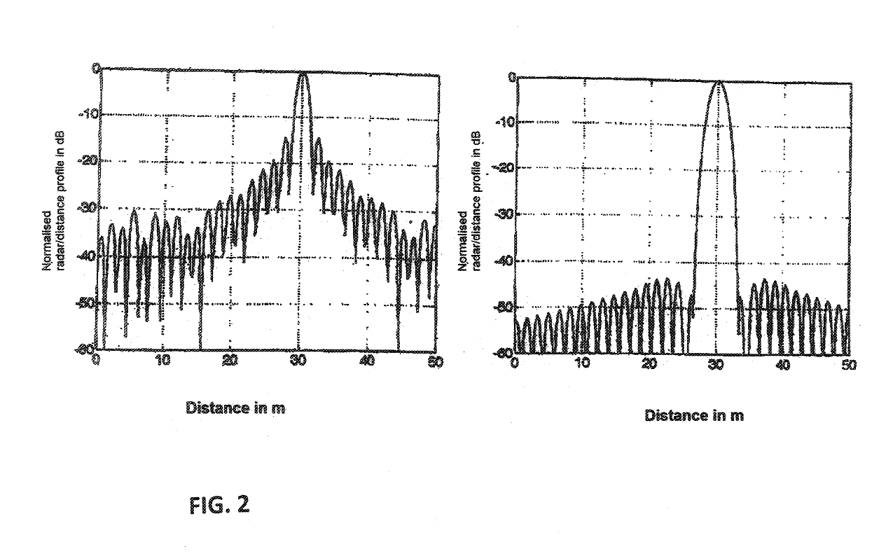

With the aid of a simulation model, the functionality of the modulation-symbol based processing was verified and also its performance was compared with the classical approach of cross correlation in accordance with Equation (1). The images illustrated in FIG. 2 show a radar simulation for a pinpoint target at a distance of 30 m. The left image shows the result of classical processing, the right image shows the result of modulation-symbol based processing in accordance with Equations (5) and (6). It can clearly be seen from the figure that in classical processing, substantially higher side lobes arise than in the case of processing in accordance with the suggested method. These side lobes result from the autocorrelation properties of the incidental data, using which the signal was modulated, and cannot be reduced by means of suitable technologies, such as e.g. windowing. The dynamic range is strongly limited as a result, which makes object detection in scenarios with many objects practically impossible. In modulation-symbol based processing in accordance with the suggested method, the side lobes can be brought to a constant very low value with the aid of windowing. A Hamming window was used for the result in the right image of FIG. 2. The side lobes are here exclusively caused by the Fourier transformation. Side lobes due to poor autocorrelation properties cannot arise in principle in modulation-symbol based processing.

The realisation of the Doppler processing or the determining of the speed likewise takes place on the basis of the modulation symbols normalised in accordance with Equation (5). In this case, however, temporally consecutive modulation symbols are considered. The analysis takes place in each case by means of a defined frame made up of M OFDM symbols. For any desired OFDM subcarrier n, the Doppler spectrum is calculated with the aid of a discrete Fourier transformation

$$S ( v , n ) = {\sum }_{μ = 0}^{M - 1} {I}_{div} ( n , μ ) exp ( - j \frac{2 π}{M} μ v ) , v = 0 , … , M - 1 \qquad ( 7 )$$

wherein v is the discrete frequency variable.

Preferably, the two above method variants for determining the distance and for determining the speed are combined to form a two-dimensional method which enables an independent processing of distance and speed. The entire processing takes place in this processing method in three steps starting from the received signal:

### 1st Step: Normalisation by Means of Complex Division

The received modulation symbols are normalised by means of a complex division before the channel equalisation with the aid of the transmitted modulation symbols in accordance with Equation (5).

### 2nd Step: Fourier Transformation in the Temporal Direction

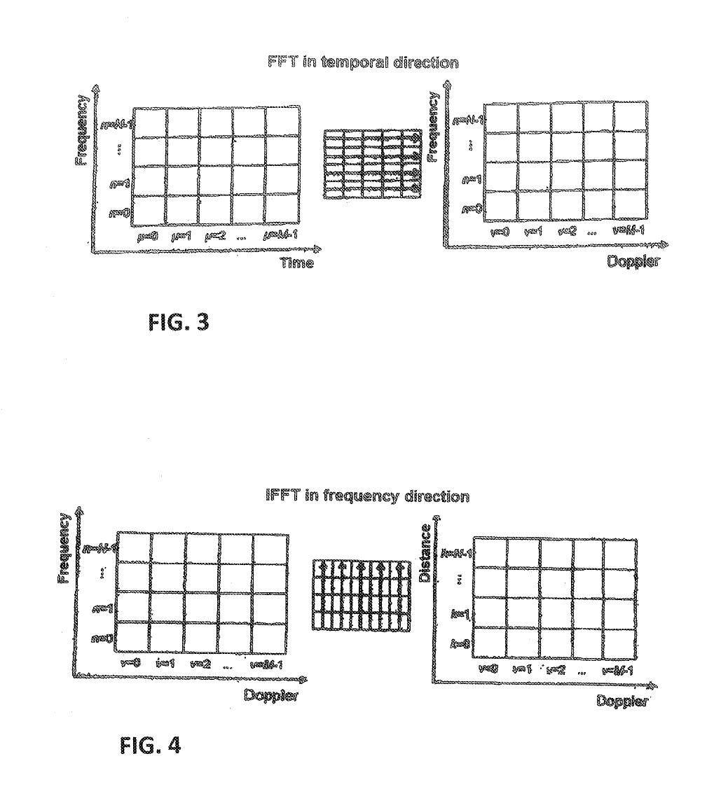

To determine the speed, a discrete Fourier transformation in the temporal direction is calculated in the normalised modulation symbol matrix for each OFDM subcarrier within a frame of length M. The result is a matrix in which the time axis is replaced with a Doppler axis which represents the Doppler shift. This is shown in FIG. 3.

### 3rd Step: Inverse Fourier Transformation in the Frequency Direction

To determine the distance, an inverse discrete Fourier transformation in the frequency direction is calculated in the result matrix of step 2 for each OFDM symbol within a frame of length M. The result is a matrix in which a two-dimensional radar image with the dimensions distance and Doppler shift is contained. The 3rd processing step is shown in FIG. 4.

The sequence of steps 2 and 3 can be reversed. Alternatively, both steps can be combined and replaced with a two-dimensional discrete Fourier transformation or a two-dimensional discrete inverse Fourier transformation with subsequent mirroring of the matrix.

FIG. 5 shows an example result from the simulation for the processing of three pinpoint targets of the same reflectivity with an OFDM signal made up of N=1024 subcarriers with a distance of Δf=90.909 kHz over a frame duration of M=128. The simulated objects have the following distances and speeds in this case:

| | Distance | Speed |
|---|---|---|
| Object 1 | 33.2 m | 10 m/s |
| Object 2 | 33.2 m | 14 m/s |
| Object 3 | 35 m | 10 m/s |

In the processed radar image, all three objects are clearly depicted in terms of distance and speed. A link between distance and speed does not occur. Objects at the same distance with the same speed can be separated, as can be seen from FIG. 5.

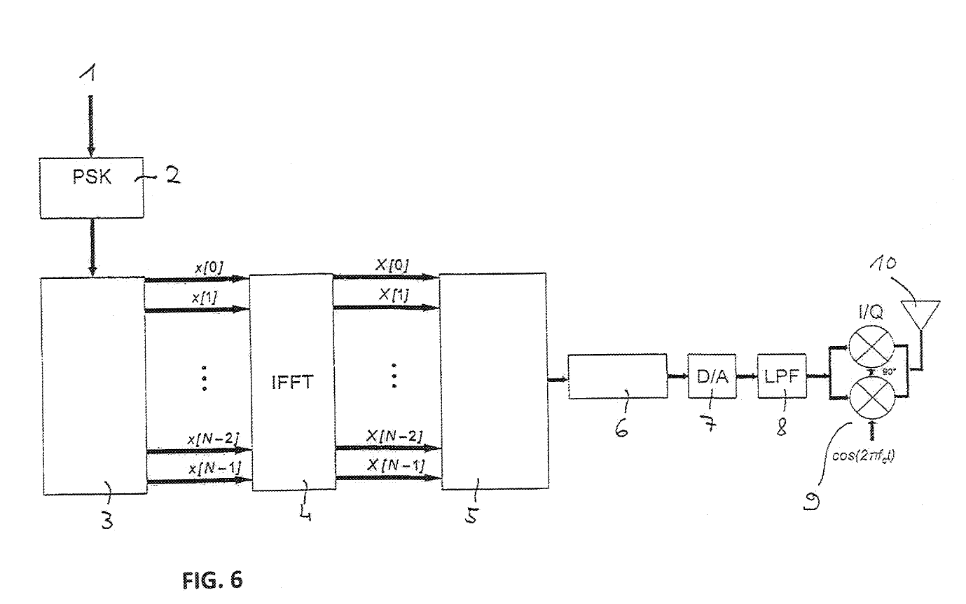

FIG. 6 finally shows an example for a transmission apparatus for emitting the OFDM radar signals. The input bits 1 which represent the information to be transmitted are initially converted in a digital modulator 2, in the present example by means of PSK, into complex modulation symbols, i.e. into modulation symbols with a complex value (I, Q). A serial/parallel conversion of the data stream is carried out with the aid of a serial/parallel converter 3.

Here, the serial data stream is in each case divided into N parallel data sequences which are assigned to N subcarriers. A digital time-discrete OFDM signal is formed in a Fourier transformation unit 4 with the aid of an inverse discrete fast Fourier transformation (IFFT) for the currently parallel applied modulation symbols forming an OFDM signal in each case, which ODM signal is subsequently serialised in a parallel/serial converter 5. After the addition of a cyclically repeated section (cyclic prefix) of the signal obtained in this manner (unit 6) to prevent intersymbol interference, the digital signal stream is converted to an analogue transmission signal in a digital/analogue converter 7, which, after passing a low-pass filter 8 and also a mixing unit 9, is emitted on a high-frequency carrier as a radar signal by means of the transmission antenna 10. A transmission apparatus of this type is known to the person skilled in the art from the field of OFDM radar technology or OFDM information transmission technology.

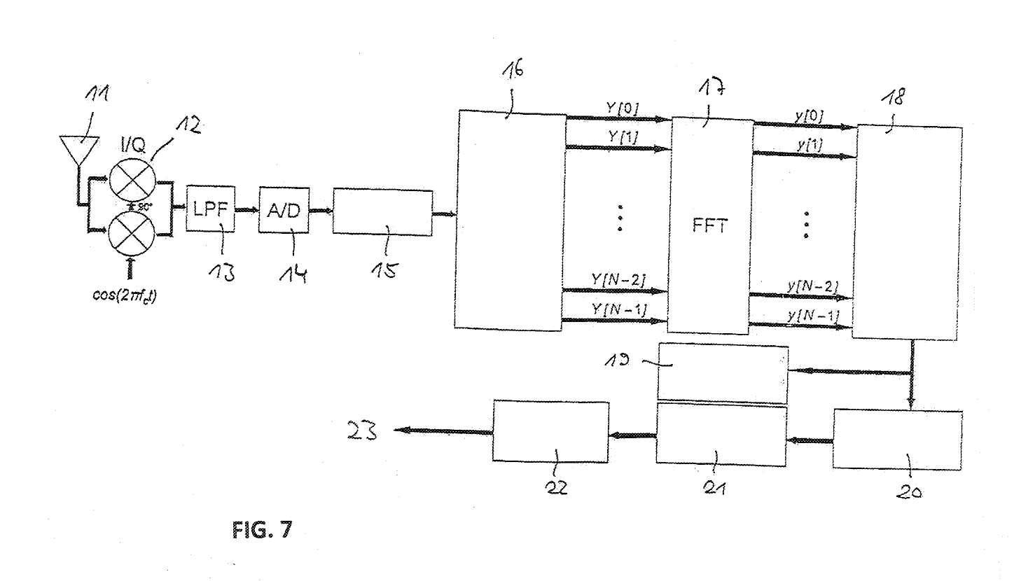

An example for a receiving apparatus, which can also be arranged in the same device as the transmission apparatus, is illustrated schematically in FIG. 7. In this receiving apparatus, the radar signal reflected by the objects is received by means of the receiving antenna 11, downmixed to baseband again in a mixing unit 12 and, after passing a low-pass filter 13, converted to a digital signal in an analogue/digital converter 14. In the case of an application for OFDM radar, the same high-frequency oscillator is typically used for controlling the mixing unit 9 in the transmitter and the mixing unit 12 in the receiver. Subsequently, in the receiver, the cyclic prefix (unit 15) is removed and the digital signal is parallelised in a serial/parallel converter 16 in accordance with the number of subcarriers, in order to subject the individual channels to a discrete fast Fourier transformation (FFT unit 17) and to convert the same to a serial signal again in a parallel/serial converter 18. In a conventional receiving apparatus, the serial signal is fed to a channel equalisation unit 20, in which the sampled values of the individual channels are equalised. Following the equalisation, a detection of the modulation symbols takes place in an extraction unit 21 and a conversion of the modulation symbols to the transmitted data bits, which are then available as output bits 23, takes place in a demodulator 22.

Alternatively or additionally to the channel equalisation apparatus 20, the extraction unit 21 and the demodulator 22, the receiving apparatus of the device suggested here has a processing unit 19 which extracts the modulation symbols without prior channel equalisation, normalises the same to the transmitted modulation symbols and carries out the calculation of the speeds and/or distances of the objects or the corresponding radar images on the basis of the normalised modulation symbols.

In addition to the I/Q mixing unit 12, an analogue/digital converter 14 and also FFT or IFFT processors, which are accessed by the processing unit 19, are required as hardware components for the realisation of a receiving apparatus of this type.

The method can for example be carried out in the ISM band at 24 GHz, as a signal bandwidth of approximately 100 MHz can be used here globally without a licence. When choosing the carrier frequency, it is fundamentally true that the wavelength should be smaller than the reflecting structures. At the same time, the carrier frequency also must not be too high, as otherwise, the propagation damping is too high and only an application over short distances is therefore possible.

### LIST OF REFERENCE SIGNS

1 Input bits
2 Modulator
3 Serial/parallel converter
4 Fourier transformation unit
5 Parallel/serial converter
6 Unit for adding a prefix
7 Digital/analogue converter
8 Low-pass filter
9 Mixing unit
10 Transmission antenna
11 Receiving antenna
12 Mixing unit
13 Low-pass filter
14 Analogue/digital converter
15 Unit for removing the prefix
16 Serial/parallel converter
17 FFT unit
18 Parallel/serial converter
19 Processing unit
20 Channel equalisation unit
21 Extraction unit
22 Demodulator
23 Output bits

1. Method for digitally processing OFDM signals which are transmitted by a transmission apparatus with modulation symbols as information carriers, reflected at one or a plurality of objects at least to some extent and received by a receiving apparatus, in which
the modulation symbols are extracted without prior channel equalisation from the OFDM signals received,
some or all extracted modulation symbols are normalised by a complex division to the respectively transmitted modulation symbol, and
a radar analysis for determining the distance and/or determining the speed of the objects takes place on the basis of the normalised modulation symbols.

2. Method according to claim 1,
in which the determining of the distance takes place via an inverse Fourier transformation of the normalised modulation symbols of at least one OFDM symbol of the received OFDM signals.

3. Method according to claim 1 or 2,
in which the determining of the speed takes place by means of an analysis of a phase shift of temporally consecutive modulation symbols of at least one subcarrier of the OFDM signals.

4. Method according to claim 3,
in which the analysis of the phase shift takes place with the aid of a Fourier transformation of the normalised modulation symbols.

5. Method according to claim 1,
in which the determining of the distance and the determining of the speed take place simultaneously by means of a two-dimensional inverse or normal Fourier transformation of the normalised modulation symbols.

6. Method according to claim 1,
in which an inverse Fourier transformation of the normalised modulation symbols of a plurality of subcarriers of temporally consecutive OFDM symbols is carried out for the determining of the distance and the data obtained therefrom are subsequently subjected to a Fourier transformation for the determining of the speed.

7. Method according to claim 1,
in which a Fourier transformation of the normalised modulation symbols of a plurality of subcarriers of temporally consecutive OFDM symbols is carried out for the determining of the speed and the data obtained therefrom are subsequently subjected to an inverse Fourier transformation for the determining of the distance.

8. Device for digitally processing OFDM signals which are transmitted by a transmission apparatus with modulation symbols as information carriers and reflected at one or a plurality of objects at least to some extent, with
a receiving antenna (11) for receiving the OFDM signals,
a mixing apparatus (12) for downmixing the received signals,
an analogue/digital converter (14) for digitising the signals, and
a processing apparatus (19) which extracts the modulation symbols without prior channel equalisation and carries out a radar analysis for the determining of the distance and/or the determining of the speed on the basis of these modulation symbols, in particular computes radar or Doppler images.
